(19) United States
(12) Patent Application Publication
(10) Pub. No.: US 2012/0296053 A1
(43) Pub. Date: Nov. 22, 2012

(54) PHOTOSENSITIVE COMPOSITION, CURED FILM AND ELECTRONIC PART

(75) Inventors: Masaaki HANAMURA, Tokyo (JP); Futoshi YAMATO, Tokyo (JP); Akito HIRO, Tokyo (JP); Akari SAKO, Tokyo (JP); Jun MUKAWA, Tokyo (JP)

(73) Assignee: JSR CORPORATION, Tokyo (JP)

(21) Appl. No.: 13/449,724

(22) Filed: Apr. 18, 2012

(30) Foreign Application Priority Data
May 18, 2011 (JP) 2011-111209
Feb. 21, 2012 (JP) 2012-034894

(51) Int. Cl. C08G 8/28; G03F 7/012

(52) U.S. Cl. 525/480; 430/281.1

(57) ABSTRACT

A photosensitive composition capable of forming a cured film having small internal stress; a cured film formed from the composition; and an electronic part including the cured film. The photosensitive composition includes: an alkali soluble resin (A), which includes at least 80% by mass of a novolak resin; a photosensitive compound (B); and a crosslinking agent (C), which includes at least a compound represented by the following formula (C1):

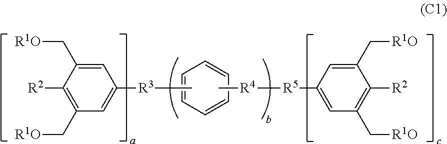

wherein R¹ is an alkyl group having 1 to 6 carbon atoms or the like; R² is hydroxyl group or the like; R³ is a (a+1)valent hydrocarbon group or the like; R⁵ is a (c+1)valent hydrocarbon group or the like; R⁴ is a single bond or the like; a and c are each independently integers of 1 to 3, wherein the sum a+c is an integer of 3 to 6; and b is an integer of 0 or more.

### TECHNICAL FIELD

The present invention relates to a photosensitive composition suitably for use in an interlaminar insulating film (passivation film), a flattening film and the like of an electronic part and the like; a cured film obtained by curing the above composition; and an electronic part comprising the above cured film.

### BACKGROUND ART

Conventionally, as a resin composition used to form an interlaminar insulating film employed for a semiconductor device in an electronic part, various photosensitive compositions have been proposed (for example, see Patent Literatures 1 to 3).

Patent Literature 1, aiming to provide a composition that achieves the improvement in adhesion after development, heat resistance and mechanical properties, discloses a positive photosensitive resin composition comprising an alkali soluble resin having phenolic hydroxyl group, a compound that generates an acid by light, a core-shell polymer and a solvent.

Patent Literature 2, aiming to provide a composition that gives a cured product having improved adhesion to a substrate, discloses a positive photosensitive resin composition comprising a novolak resin, a specific polyamide acid, a silane coupling agent having an epoxy group or an oxetanyl group, a quinone diazide compound, an alkoxymethyl group-containing compound and a solvent.

Patent Literature 3, aiming to provide a composition that reduces discoloration caused by heat treatment performed after curing, discloses a positive photosensitive resin composition comprising a novolak resin, a specific polyamide acid, an antioxidant, an oxetane group-containing compound or an isocyanate group-containing compound, a quinone diazide compound and a solvent.

In recent process for mounting semiconductor devices in electronic parts, with the increase in the diameter of a silicon wafer, as a result of curing shrinkage in the formation of an interlaminar insulating film, the insulating film has internal stress, and then the internal stress of the insulating film may cause the silicon wafer neighboring the insulating film to have warpage.

### CITATION LIST

### Patent Literatures

Patent Literature 1: JP-A-2009-237125
Patent Literature 2: JP-A-2010-008851
Patent Literature 3: JP-A-2010-026359

### SUMMARY OF THE INVENTION

### Technical Problem

It is an object of the present invention to provide a photosensitive composition capable of forming a cured film having small internal stress; a cured film formed from the above composition; and an electronic part comprising the above cured film.

### Solution to Problem

The present inventors earnestly made their studies to solve the above problem, and have found that the use of a photosensitive composition having a constitution described below can solve the above problem, thereby completing the present invention.

That is, the present invention concerns the following [1] to [5].

[1] A photosensitive composition comprising an alkali soluble resin (A), a photosensitive compound (B) and a crosslinking agent (C), wherein the photosensitive composition comprises:

at least a novolak resin (A1) as the alkali soluble resin (A), the proportion of the content of the novolak resin (A1) being 80% by mass or more of the alkali soluble resin (A); and

at least a compound represented by the following formula (C1) as the crosslinking agent (C):

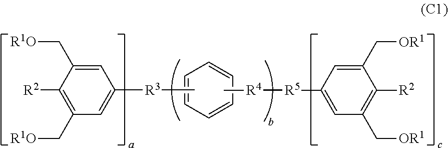

wherein R¹s are each independently a hydrogen atom, an alkyl group having 1 to 6 carbon atoms, —COR⁶ or —SO₂R⁷, wherein R⁶ is an alkyl group having 1 to 4 carbon atoms or a fluoroalkyl group having 1 to 4 carbon atoms, and R⁷ is a hydrocarbon group; R²s are each independently hydroxyl group or a hydroxyalkyl group having 1 to 4 carbon atoms; R³ is a (a+1)valent hydrocarbon group or a single bond; R⁵ is a (c+1)valent hydrocarbon group or a single bond, with the proviso that R³ and R⁵ are not single bonds at the same time; R⁴ is a single bond, methylene group or an alkylene group; “a” and “c” are each independently an integer of from 1 to 3, with the proviso that a+c is an integer of from 3 to 6; and “b” is an integer of 0 or more.

[2] The photosensitive composition as described in the above [1], wherein the proportion of the content of the compound represented by the formula (C1) is 60% by mass or more of the crosslinking agent (C).

[3] The photosensitive composition as described in the above [1] or [2], wherein the photosensitive compound (B) is a quinone diazide compound (B1).

[4] A cured film obtainable from the photosensitive composition as described in any of the above [1] to [3].

[5] An electronic part comprising the cured film as described in the above [4].

### Advantageous Effects of Invention

According to the present invention, there can be provided a photosensitive composition capable of forming a cured film having small internal stress; a cured film formed from the above composition; and an electronic part comprising the above cured film.

### BRIEF DESCRIPTION OF DRAWINGS

FIG. 1: A vertical cross-sectional figure of a base material for thermal shock resistance evaluation

FIG. 2: A top view figure of a base material for thermal shock resistance evaluation

FIG. 3: A top view figure of a base material for electrical insulating properties evaluation

### DESCRIPTION OF EMBODIMENTS

Hereinafter, the photosensitive composition, the cured film and the electronic part of the present invention are described.

### Photosensitive Composition

The photosensitive composition of the present invention comprises an alkali soluble resin (A), a photosensitive compound (B) and a crosslinking agent (C). Here, the photosensitive composition of the present invention comprises at least a novolak resin (A1) as the alkali soluble resin (A), the proportion of the content of the novolak resin (A1) being 80% by mass or more of the alkali soluble resin (A); and comprises at least a compound represented by the formula (C1) described later as the crosslinking agent (C).

### <Alkali Soluble Resin (A)>

The photosensitive composition of the present invention comprises at least a novolak resin (A1) as the alkali soluble resin (A). The proportion of the content of the novolak resin (A1) is 80% by mass or more, preferably 85% by mass or more, particularly preferably 90% by mass or more of the alkali soluble resin (A). When the proportion of the content of the novolak resin (A1) is within the above range, a photosensitive composition can be obtained which is capable of forming a cured film having small internal stress. Specifically, by using the curable composition of the present invention that uses both the novolak resin (A1) and the compound represented by the formula (C1) described later, a cured film having a structural unit represented by the following formula (K) as a main component is formed, and as a result, such a cured film has small internal stress.

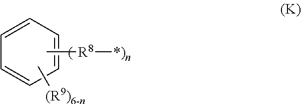

In the formula (K), R⁸s are each independently a direct bond, methylene group, an alkylene group or —CH₂O—; R⁹s are each independently a hydrogen atom, hydroxyl group or a hydroxyalkyl group having 1 to 4 carbon atoms; “n” is an integer of from 1 to 6; and “*” is a bond.

The alkali soluble resin (A) is a resin which is dissolved in an amount of 0.001 mg/mL or more in an aqueous tetramethylammonium hydroxide solution having a concentration of 2.38% by mass (23° C.). Specific examples thereof include resins having at least one kind of functional group selected from carboxylic acid group, phenolic hydroxyl group and sulfonic acid group.

Examples of the alkali soluble resin (A) include polyamide acids, which are polyimide precursors; partially-imidized products thereof; and polyhydroxyamides, which are polybenzoxazole precursors.

Examples of the alkali soluble resin (A) include alkali soluble resins having phenolic hydroxyl group. However, from the alkali soluble resin having phenolic hydroxyl group, the novolak resin (A1); the polyamide acids, which are polyimide precursors; the partially-imidized products thereof; and polyhydroxyamides, which are polybenzoxazole precursors are excluded.

The alkali soluble resins (A) may be used singly or two or more kinds may be used in combination.

The proportion of the content of the alkali soluble resin (A) is usually 30 to 90% by mass, preferably 40 to 90% by mass, more preferably 50 to 90% by mass of components excluding a solvent of the photosensitive composition of the present invention. When the proportion of the content of the alkali soluble resin (A) is within the above range, a photosensitive composition excellent in resolution is obtained.

### <<Novolak Resin (A1)>>

The novolak resin (A1) is obtainable, for example, by condensing phenols and aldehydes in the presence of an acid catalyst. Examples of the phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, catechol, resorcinol, pyrogallol, α-naphthol and β-naphthol. Examples of the aldehydes include formaldehyde, paraformaldehyde, acetaldehyde, benzaldehyde and salicylaldehyde.

Preferable specific examples of the novolak resin (A1) include phenol/formaldehyde condensed novolak resin, cresol/formaldehyde condensed novolak resin, cresol/salicylaldehyde condensed novolak resin and phenol-naphthol/formaldehyde condensed novolak resin.

The novolak resin (A1) has a weight average molecular weight (Mw), as measured by gel permeation chromatography (GPC) in terms of polystyrene, of usually 1,000 to 100,000, preferably 2,000 to 50,000, more preferably 4,000 to 30,000, in view of resolution of the photosensitive composition and thermal shock resistance and heat resistance of the cured film.

### <<Polyamide Acids, Partially-Imidized Products Thereof and Polyhydroxyamides>>

Examples of the polyamide acids, the partially-imidized products thereof and the polyhydroxyamides include resins containing a repeating structural unit represented by the formula (1) as a main component. The resin containing a repeating structural unit represented by the formula (1) as a main component can become a resin having an imide ring and/or an oxazole ring by heating or using an appropriate catalyst. The resin containing a repeating structural unit represented by the formula (1) as a main component means a resin containing the repeating structural unit represented by the formula (1) in an amount of 50 mol % or more, preferably 70 mol % or more, more preferably 90 mol % or more of all the repeating structural units of the resin.

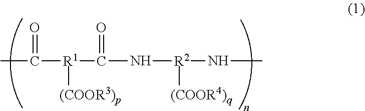

Each denotation in the formula (1) is as described below:

R¹s are each independently a (2+p)valent organic group having 2 or more carbon atoms; preferably a tetravalent organic group; more preferably a group derived from tetracarboxylic acid dianhydride having 6 to 30 carbon atoms. In view of heat resistance of the resultant resin, R¹ preferably has an aromatic ring. R¹ may have one to four hydroxyl groups. In view of solubility in an alkaline developing solution and photosensitivity, the amount of R¹ having hydroxyl group is preferably 50 mol % or more, more preferably 70 mol % or more of all of R¹s.

R²s are each independently an (2+q)valent organic group having 2 or more carbon atoms; preferably a group derived from a diamine having 2 to 50 carbon atoms. In terms of heat resistance of the resultant resin, R² preferably has an aromatic ring. R² may have one to four hydroxyl groups.

In order to improve the adhesion between the coating film and the substrate, in a range which does not reduce heat resistance of the coating film, an aliphatic group having a siloxane structure may be introduced as R¹ and/or R². R² having the aliphatic group is introduced preferably in an amount of 1 to 20 mol % of all of R²s. R¹ having the aliphatic group is introduced preferably in an amount of 1 to 20 mol % of all of R¹s.

R³ and R⁴ are each independently hydrogen or a monovalent organic group (e.g., hydrocarbon group) having 1 to 20 carbon atoms. “p” and “q” are each independently an integer of from 0 to 2, preferably p=2 and q=0. “n” is an integer of from 10 to 100,000, preferably an integer of from 10 to 1,000, more preferably an integer of from 20 to 100.

The terminal of the resin containing a repeating structural unit represented by the formula (1) as a main component may be reacted with a terminal-blocking agent. The preferred terminal-blocking agent is a compound having at least one kind of functional group selected from hydroxyl group, carboxyl group, sulfonic acid group, thiol group, vinyl group, ethynyl group and allyl group.

### <<Alkali Soluble Resin Having Phenolic Hydroxyl Group>>

Examples of the alkali soluble resin having phenolic hydroxyl group include homopolymers or copolymers of monomers having phenolic hydroxyl group such as p-hydroxystyrene, m-hydroxystyrene, o-hydroxystyrene, p-isopropenylphenol, m-isopropenylphenol and o-isopropenylphenol; phenol-xylylene glycol condensed resin; cresol-xylylene glycol condensed resin; and phenol-dicyclopentadiene condensed resin.

### <Photosensitive Compound (B)>

The photosensitive composition of the present invention may be a positive photosensitive composition or may be a negative photosensitive composition. The photosensitive compound (B) is appropriately selectable depending on the positive photosensitive composition or the negative photosensitive composition.

As the photosensitive compound (B), a compound having a quinone diazide group (hereinafter also referred to as a “quinone diazide compound (B1)”) and the like can be mentioned for the positive photosensitive composition; and a photosensitive acid-generating agent (hereinafter also referred to as an “acid-generating agent (B2)”) and the like can be mentioned for the negative photosensitive composition.

### <<Quinone Diazide Compound (B1)>>

The quinone diazide compound (B1) is an ester compound formed between a compound having one or more phenolic hydroxyl groups and 1,2-naphthoquinone diazide-4-sulfonic acid or 1,2-naphthoquinone diazide-5-sulfonic acid.

The photosensitive composition comprising the quinone diazide compound (B1) gives a coating film that is hardly dissolved in an alkaline developing solution. The quinone diazide compound (B1) is a compound in which the quinone diazide group is decomposed by light irradiation to generate carboxyl group, and thus this coating film, when irradiated with light, changes its state from being at an alkali hardly-soluble state to being at an alkali easily-soluble state; by utilizing this property, a positive pattern can be formed.

Examples of the compound having one or more phenolic hydroxyl groups include compounds represented by the following formulae (B1-1) to (B1-5). These compounds may be used singly or two or more kinds may be used in combination.

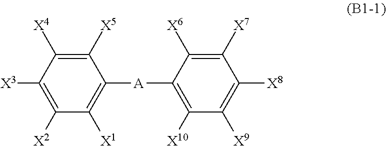

In the formula (B1-1), X¹ to X¹⁰ are each independently a hydrogen atom, an alkyl group having 1 to 4 carbon atoms, an alkoxy group having 1 to 4 carbon atoms or hydroxyl group; at least one of X¹ to X⁵ is hydroxyl group; and “A” is a single bond, —O—, —S—, —CH₂—, —C(CH₃)₂—, —C(CF₃)₂—, carbonyl group (—C(═O)—) or sulfonyl group (—S(═O)₂—).

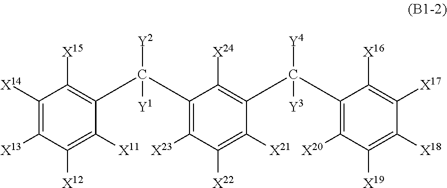

In the formula (B1-2), X¹¹ to X²⁴ are each independently a hydrogen atom, an alkyl group having 1 to 4 carbon atoms, an alkoxy group having 1 to 4 carbon atoms or hydroxyl group; at least one of X¹¹ to X¹⁵ is hydroxyl group; and Y¹ to Y⁴ are each independently a hydrogen atom or an alkyl group having 1 to 4 carbon atoms.

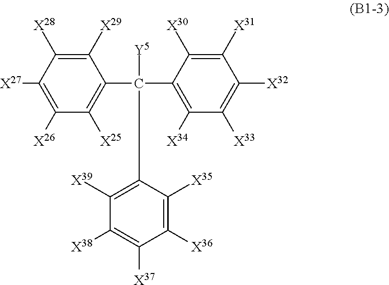

In the formula (B1-3), X²⁵ to X³⁹ are each independently a hydrogen atom, an alkyl group having 1 to 4 carbon atoms, an alkoxy group having 1 to 4 carbon atoms or hydroxyl group; at least one of X²⁵ to X²⁹ is hydroxyl group; at least one of X³⁰ to X³⁴ is hydroxyl group; and Y⁵ is a hydrogen atom or an alkyl group having 1 to 4 carbon atoms.

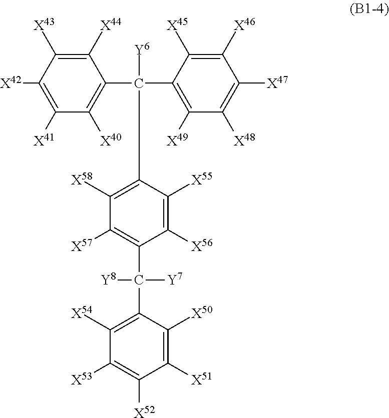

In the formula (B1-4), X⁴⁰ to X⁵⁸ are each independently a hydrogen atom, an alkyl group having 1 to 4 carbon atoms, an alkoxy group having 1 to 4 carbon atoms or hydroxyl group; at least one of X⁴⁰ to X⁴⁴ is hydroxyl group; at least one of X⁴⁵ to X⁴⁹ is hydroxyl group; at least one of X⁵⁰ to X⁵⁴ is hydroxyl group; and Y⁶ to Y⁸ are each independently a hydrogen atom or an alkyl group having 1 to 4 carbon atoms.

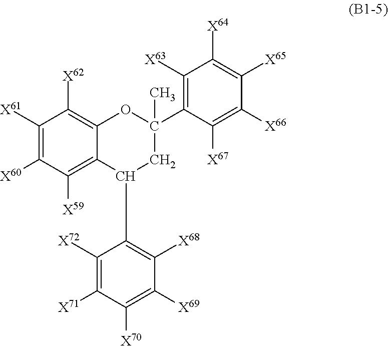

In the formula (B1-5), X⁵⁹ to X⁷² are each independently a hydrogen atom, an alkyl group having 1 to 4 carbon atoms, an alkoxy group having 1 to 4 carbon atoms or hydroxyl group; at least one of X⁵⁹ to X⁶² is hydroxyl group; and at least one of X⁶³ to X⁶⁷ is hydroxyl group.

Examples of the quinone diazide compound (B) include

ester compounds formed between
4,4′-dihydroxydiphenylmethane,
4,4′-dihydroxydiphenyl ether,
2,3,4-trihydroxybenzophenone,
2,3,4,4′-tetrahydroxybenzophenone,
2,3,4,2′,4′-pentahydroxybenzophenone,
tris(4-hydroxyphenyl)methane,
tris(4-hydroxyphenyl)ethane,
1,1-bis(4-hydroxyphenyl)-1-phenylethane,
1,3-bis[1-(4-hydroxyphenyl)-1-methylethyl]benzene,
1,4-bis[1-(4-hydroxyphenyl)-1-methylethyl]benzene,
4,6-bis[1-(4-hydroxyphenyl)-1-methylethyl]-1,3-dihydroxybenzene,
1,1-bis(4-hydroxyphenyl)-1-[4-[1-(4-hydroxyphenyl)-1-methylethyl]p henyl]ethane or the like, and
1,2-naphthoquinone diazide-4-sulfonic acid or
1,2-naphthoquinone diazide-5-sulfonic acid.

The quinone diazide compounds (B1) may be used singly or two or more kinds may be used in combination.

In the positive photosensitive composition of the present invention, the content of the quinone diazide compound (B1) is usually 5 to 50 parts by mass, preferably 10 to 30 parts by mass, more preferably 15 to 30 parts by mass based on 100 parts by mass of the alkali soluble resin (A). When the content of the quinone diazide compound (B1) is not less than the above lower limit, the film remaining percentage of an unexposed part is improved and a film is easily patterned with fidelity to a mask pattern. When the content of the quinone diazide compound (B1) is not more than the above upper limit, a cured film excellent in pattern shape is easily obtained and foaming during curing can be prevented.

### <<Acid-Generating Agent (B2)>>

The acid-generating agent (B2) is a compound to form an acid by light irradiation. This acid acts on the crosslinking agent (C) and thereby a crosslinked structure is formed. For example, in the case of a compound represented by the formula (C1) described later, OR¹ group in the compound represented by the formula (C1) and a phenol ring in the alkali soluble resin (A) are reacted with each other involving dealcoholization and the like, and thereby a crosslinked structure is formed. By the formation of the crosslinked structure, the coating film obtained from the photosensitive composition comprising the acid-generating agent (B2) changes its state from being at an alkali easily-soluble state to being at an alkali hardly-soluble state; by utilizing this property, a negative pattern can be formed.

Examples of the acid-generating agent (B2) include onium salt compounds, halogen-containing compounds, sulfone compounds, sulfonic acid compounds, sulfonimide compounds and diazomethane compounds.

Examples of the onium salt compounds include iodonium salts, sulfonium salts, phosphonium salts, diazonium salts and pyridinium salts. As a preferable onium salt, specific examples include diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium p-toluenesulfonate, triphenylsulfonium hexafluoroantimonate, 4-t-butylphenyl-diphenylsulfonium trifluoromethanesulfonate, 4-t-butylphenyl-diphenylsulfonium p-toluenesulfonate and 4,7-di-n-butoxynaphthyltetrahydrothiophenium trifluoromethanesulfonate.

Examples of the halogen-containing compounds include haloalkyl group-containing hydrocarbon compounds and haloalkyl group-containing heterocyclic compounds. As a preferable halogen-containing compound, specific examples include 1,10-dibromo-n-decane, 1,1-bis(4-chlorophenyl)-2,2,2-trichloroethane and s-triazine derivatives such as phenyl-bis(trichloromethyl)-s-triazine, 4-methoxyphenyl-bis(trichloromethyl)-s-triazine, styryl-bis(trichloromethyl)-s-triazine and naphthyl-bis(trichloromethyl)-s-triazine.

Examples of the sulfone compounds include β-ketosulfone compounds, β-sulfonylsulfone compounds and α-diazo compounds of these compounds. As a preferable sulfone compound, specific examples include 4-trisphenacylsulfone, mesitylphenacylsulfone and bis(phenacylsulfonyl)methane.

Examples of the sulfonic acid compounds include alkylsulfonic acid esters, haloalkylsulfonic acid esters, arylsulfonic acid esters and iminosulfonates. As a preferable sulfonic acid compound, specific examples include benzointosylate, pyrogallol tristrifluoromethanesulfonate, o-nitrobenzyl trifluoromethanesulfonate and o-nitrobenzyl p-toluenesulfonate.

Examples of the sulfonimide compounds include N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hepto-5-en-2,3-dicarboxyimide and N-(trifluoromethylsulfonyloxy)naphthylimide.

Examples of the diazomethane compounds include bis(trifluoromethylsulfonyl)diazomethane, bis(cyclohexylsulfonyl)diazomethane and bis(phenylsulfonyl)diazomethane.

The acid-generating agents (B2) may be used singly or two or more kinds may be used in combination.

In the negative photosensitive composition of the present invention, the content of the acid-generating agent (B2) is usually 0.1 to 10 parts by mass, preferably 0.3 to 5 parts by mass, more preferably 0.5 to 5 parts by mass based on 100 parts by mass of the alkali soluble resin (A). When the content of the acid-generating agent (B2) is not less than the above lower limit, curing at an exposed part is sufficient and heat resistance is easily improved. If the content of the acid-generating agent (B2) is more than the above upper limit, the transparency with respect to exposure light may be lowered and resolution may be decreased.

### <Crosslinking Agent (C)>

The crosslinking agent (C), by reacting with the alkali soluble resin (A), serves as forming a crosslinked structure in the cured film. The photosensitive composition of the present invention comprises at least a compound represented by the following formula (C1) (hereinafter also referred to as a “crosslinking agent (C1)”) as the crosslinking agent (C). The photosensitive composition of the present invention may comprise a crosslinking agent (C2) other than the crosslinking agent (C1).

In the photosensitive composition of the present invention, the content of the crosslinking agent (C) is usually 1 to 60 parts by mass, preferably 5 to 50 parts by mass, more preferably 5 to 40 parts by mass based on 100 parts by mass of the alkali soluble resin (A). When the content of the crosslinking agent (C) is within the above range, curing reaction sufficiently progresses, and the resultant cured film has high resolution and good pattern shape as well as has small internal stress and excellent heat resistance and electrical insulating properties.

### <<Crosslinking Agent (C1)>>

The crosslinking agent (C1) is represented by the following formula (C1).

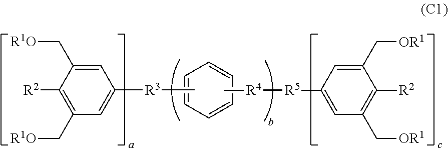

Each denotation in the formula (C1) is as described below:

R¹s are each independently a hydrogen atom, an alkyl group having 1 to 6 carbon atoms, —COR⁶ or —SO₂R⁷, preferably an alkyl group having 1 to 6 carbon atoms. R²s are each independently hydroxyl group or a hydroxyalkyl group having 1 to 4 carbon atoms, preferably hydroxyl group.

R⁶ is an alkyl group having 1 to 4 carbon atoms (for example, methyl group, ethyl group, n-propyl group, isopropyl group, n-butyl group or tert-butyl group) or a fluoroalkyl group having 1 to 4 carbon atoms (for example, trifluoromethyl group or pentafluoroethyl group).

R⁷ is a hydrocarbon group, preferably a hydrocarbon group having 1 to 6 carbon atoms (for example, methyl group, ethyl group, n-propyl group, isopropyl group, n-butyl group, tert-butyl group or phenyl group).

R³ is a (a+1)valent hydrocarbon group or a single bond. The (a+1)valent hydrocarbon group is preferably a hydrocarbon group having 1 to 12 carbon atoms, more preferably 1 to 10 carbon atoms, still more preferably 1 to 6 carbon atoms; and the (a+1)valent hydrocarbon group is preferably a saturated hydrocarbon group, more preferably a noncyclic saturated hydrocarbon group.

R⁵ is a (c+1)valent hydrocarbon group or a single bond. The (c+1)valent hydrocarbon group is preferably a hydrocarbon group having 1 to 12 carbon atoms, more preferably 1 to 10 carbon atoms, still more preferably 1 to 6 carbon atoms; and the (c+1)valent hydrocarbon group is preferably a saturated hydrocarbon group, more preferably a noncyclic saturated hydrocarbon group.

R³ and R⁵ are not single bonds at the same time.

R⁴ is a single bond, methylene group or an alkylene group. The alkylene group is preferably an alkylene group having 2 to 12 carbon atoms, more preferably 2 to 10 carbon atoms, still more preferably 2 to 6 carbon atoms.

“a” and “c” are each independently an integer of from 1 to 3, with the proviso that a+c is an integer of from 3 to 6, preferably an integer of from 3 to 4. When a+c is 3 or more, i.e., when three or more groups each represented by the following formula (i) are present, after crosslinking, the cured film can have a branched structure. “b” is an integer of 0 or more, preferably an integer of from 0 to 6, more preferably 0 or 1.

“a” denotes the number of groups each represented by the following formula (i) and possessed by R³ (“c” denotes the number of groups each represented by the following formula (i) and possessed by R⁵). “b” denotes the number of repeating structural units each represented by the following formula (ii).

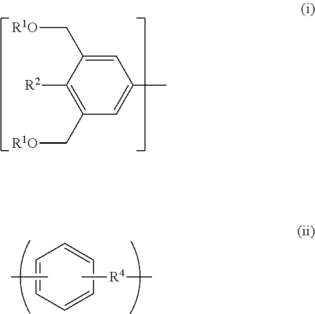

In a particularly preferable embodiment of the formula (C1), in view of improving resolution of the photosensitive composition and heat resistance of the cured film and reducing internal stress of the cured film, R¹s are each independently an alkyl group having 1 to 6 carbon atoms; R² is hydroxyl group; R³ is a (a+1)valent noncyclic saturated hydrocarbon group having 1 to 6 carbon atoms or a single bond; R⁵ is a (c+1)valent noncyclic saturated hydrocarbon group having 1 to 6 carbon atoms or a single bond; R⁴ is a single bond, methylene group or an alkylene group having 2 to 3 carbon atoms; “a” and “c” are each independently an integer of from 1 to 3, with the proviso that a+c is an integer of from 3 to 6 and “b” is 0 or 1.

Specific examples of the crosslinking agents (C1) include the crosslinking agents (C1-1) and (C1-2) described in Examples.

The crosslinking agents (C1) may be used singly or two or more kinds may be used in combination.

The proportion of the content of the crosslinking agent (C1) is preferably 60% by mass or more, more preferably 65% by mass or more of the crosslinking agent (C). When the content of the crosslinking agent (C1) in the crosslinking agent (C) is within the above range, a photosensitive composition is obtained which easily forms a cured film having the structural unit represented by the formula (K) as a main component.

### <<Crosslinking Agent (C2)>>

Examples of the crosslinking agent (C2) include compounds having two or more alkyl-etherified amino groups (hereinafter also referred to as an “amino group-containing compound”), oxirane ring-containing compounds, oxetanyl group-containing compounds, isocyanate group-containing compounds (including blocked compounds), aldehyde group-containing phenol compounds and methylol group-containing phenol compounds (excluding the crosslinking agent (C1)).

The crosslinking agents (C2) may be used singly or two or more kinds may be used in combination.

Examples of the amino group-containing compounds include compounds obtainable by alkyl-etherifying all of or part of (at least two) active methylol groups (CH₂OH group) in a nitrogen compound, such as (poly)methylolated melamine, (poly)methylolated glycoluril, (poly)methylolated benzoguanamine and (poly)methylolated urea. The alkyl groups for alkyl-etherification include methyl group, ethyl group and butyl group and may be the same as or different from one another. The methylol groups without alkyl-etherification may be self-condensed in one molecule, or may be condensed between two molecules to form an oligomer component. Specific employable examples include hexamethoxymethylmelamine, hexabutoxymethylmelamine, tetramethoxymethylglycoluril and tetrabutoxymethylglycoluril.

The oxirane ring-containing compounds are not particularly limited as long as containing an oxirane ring in the molecule. Example thereof include phenol novolak epoxy resin, cresol novolak epoxy resin, bisphenol epoxy resin, trisphenol epoxy resin, tetraphenol epoxy resin, phenol-xylylene epoxy resin, naphthol-xylylene epoxy resin, phenol-naphthol epoxy resin, phenol-dicyclopentadiene epoxy resin, alicyclic epoxy resin and aliphatic epoxy resin.

As the crosslinking agent (C2), the amino group-containing compound and the oxirane ring-containing compound are preferable. The amino group-containing compound and the oxirane ring-containing compound may be used in combination. When these are used in combination, provided that the total amount of the amino group-containing compound and the oxirane ring-containing compound is 100% by mass, the proportion of the content of the oxirane ring-containing compound is preferably 50% by mass or less, more preferably 5 to 40% by mass. When these compounds are used in the above mass ratio, a cured film excellent in chemical resistance can be formed without impairing high resolution.

### <Adhesion Assistant (D)>

The photosensitive composition of the present invention, in order to have improved adhesion to a substrate, may further comprise an adhesion assistant (D). A preferred example of the adhesion assistant is a functional silane coupling agent, for example a silane coupling agent having a reactive substituent such as carboxyl group, methacryloyl group, vinyl group, isocyanate group and epoxy group. Specific examples thereof include trimethoxysilylbenzoic acid, γ-methacryloxypropyltrimethoxysilane, vinyltriacetoxysilane, vinyltrimethoxysilane, γ-isocyanato propyltriethoxysilane, γ-glycidoxypropyltrimethoxysilane, β-(3,4-epoxycyclohexyl)ethyltrimethoxysilane and 1,3,5-N-tris(trimethoxysilylpropyl)isocyanurate.

In the photosensitive composition of the present invention, the content of the adhesion assistant (D) is preferably 0.5 to 10 parts by mass, more preferably 0.5 to 5 parts by mass based on 100 parts by mass of the alkali soluble resin (A). When the content of the adhesion assistant (D) is within the above range, the adhesion to a substrate of a cured product obtained by curing the photosensitive composition of the present invention is further improved.

### <Crosslinked Fine Particles (E)>

The photosensitive composition of the present invention, in order to allow the cured film to have improved insulating properties and thermal shock resistance, may further comprise crosslinked fine particles (E). Examples of the crosslinked fine particles (E) include crosslinked fine particles of a copolymer of a monomer having hydroxyl group and/or carboxyl group (hereinafter also referred to as a “functional group-containing monomer”) with a crosslinkable monomer having two or more polymerizable unsaturated groups (hereinafter referred to as a “crosslinkable monomer”). Further, crosslinked fine particles of a copolymer obtained by further copolymerizing another monomer may be used.

Examples of the functional group-containing monomer include hydroxyl group-containing unsaturated compounds such as hydroxyethyl(meth)acrylate, hydroxypropyl(meth)acrylate and hydroxybutyl(meth)acrylate; and unsaturated acid compounds such as (meth)acrylic acid, itaconic acid, succinic acid-β-(meth)acryloxyethyl, maleic acid-β-(meth)acryloxyethyl, phthalic acid-β-(meth)acryloxyethyl and hexahydrophthalic acid-β-(meth)acryloxyethyl. The functional group-containing monomers may be used singly or two or more kinds may be used in combination.

The proportion of the content of a structural unit derived from the functional group-containing monomer is usually 5 to 90 mol %, preferably 5 to 70 mol %, more preferably 5 to 50 mol % in terms of a value calculated from an acid value or a hydroxyl value as measured in accordance with JIS K 0070, provided that the amount of all of the structural units derived from monomers in the crosslinked fine particles (E) is 100 mol %.

Examples of the crosslinkable monomer include compounds having plural polymerizable unsaturated groups such as divinylbenzene, diallylphthalate, ethylene glycol di(meth)acrylate, propylene glycol di(meth)acrylate, trimethylolpropane tri(meth)acrylate, pentaerythritol tri(meth)acrylate, polyethylene glycol di(meth)acrylate and polypropylene glycol di(meth)acrylate. Divinylbenzene is preferable. The crosslinkable monomers may be used singly or two or more kinds may be used in combination.

The proportion of the content of a structural unit derived from the crosslinkable monomer is preferably 0.5 to 20 mol %, more preferably 0.5 to 10 mol %, provided that the amount of all of the structural units derived from monomers in the crosslinked fine particles (E) is 100 mol %. When the proportion of the content is within the above range, the fine particles can have stabilized shape.

Examples of the other monomer include:

diene compounds such as butadiene, isoprene, dimethyl butadiene, chloroprene and 1,3-pentadiene;

unsaturated nitrile compounds such as (meth)acrylonitrile, α-chloroacrylonitrle, α-chloromethylacrylonitrile, α-methoxyacrylonitrile, α-ethoxyacrylonitrile, nitrile crotonate, nitrile cinnamate, dinitrile itaconate, dinitrile maleate and dinitrile fumarate;

unsaturated amides such as (meth)acrylamide, dimethyl(meth)acrylamide, N,N′-methylenebis(meth)acrylamide, N,N′-ethylenebis(meth)acrylamide, N,N′-hexamethylenebis(meth)acrylamide, N-hydroxymethyl(meth)acrylamide, N-(2-hydroxyethyl)(meth)acrylamide, N,N-bis(2-hydroxyethyl)(meth)acrylamide, crotonic acid amide and cinnamic acid amide;

(meth)acrylic acid esters such as methyl (meth)acrylate, ethyl (meth)acrylate, propyl (meth)acrylate, butyl (meth)acrylate, hexyl (meth)acrylate, lauryl (meth)acrylate, polyethylene glycol (meth)acrylate and polypropylene glycol (meth)acrylate;

aromatic vinyl compounds such as styrene, α-methyl styrene, o-methoxystyrene, p-hydroxystyrene and p-isopropenyl phenol;

epoxy (meth)acrylates obtained by reaction of bisphenol A diglycidyl ether, a glycol diglycidyl ether or the like with (meth)acrylic acid, a hydroxyalkyl (meth)acrylate or the like; urethane (meth)acrylates obtained by reaction of a hydroxyalkyl (meth)acrylate with a polyisocyanate; epoxy group-containing unsaturated compounds such as glycidyl (meth)acrylate and (meth)allyl glycidyl ether; and

amino group-containing unsaturated compounds such as dimethyl amino(meth)acrylate and diethyl amino(meth)acrylate.

Of these other monomers, diene compounds, styrene and acrylonitriles are preferable; and in particular, butadiene and styrene are more preferable. These other monomers may be used singly or two or more kinds may be used in combination.

The proportion of the content of a structural unit derived from the other monomer is preferably 9.5 to 94.5 mol %, more preferably 29.5 to 94.5 mol %, provided that the amount of all of the structural units derived from monomers in the crosslinked fine particles (E) is 100 mol %.

The crosslinked fine particles (E) may be used singly or two or more kinds may be used in combination.

The glass transition temperature (Tg) of the copolymer constituting the crosslinked fine particles (E) is preferably 20° C. or lower, more preferably 10° C. or lower, still more preferably 0° C. or lower. If Tg of the crosslinked fine particles (E) is higher than the above value, the cured film may have cracking. The lower limit of Tg of the crosslinked fine particles (E) is usually −70° C.

The crosslinked fine particles (E) are fine particles of copolymers. The average primary particle diameter of the crosslinked fine particles (E) is usually 30 to 500 nm, preferably 40 to 200 nm, more preferably 50 to 120 nm. As a method to control the average primary particle diameter of the crosslinked fine particles (E), for example, in the case where the crosslinked fine particles are prepared by emulsion polymerization, adjusting the amount of an emulsifying agent to be used thereby controlling the number of micelles during emulsion polymerization can control the average primary particle diameter.

The average primary particle diameter of the crosslinked fine particles (E) is a value determined by diluting a dispersion of the crosslinked fine particles (E) through an ordinary method and measuring the diameters using a particle size distribution measuring apparatus by light scattering LPA-3000 manufactured by Otsuka Electronics Co. Ltd.

In the photosensitive composition of the present invention, the content of the crosslinked fine particles (E) is preferably 0 to 200 parts by mass, more preferably 0.1 to 150 parts by mass, still more preferably 0.5 to 100 parts by mass based on 100 parts by mass of the alkali soluble resin (A).

### <Solvent (F)>

The photosensitive composition of the present invention may further comprise a solvent (F) in order to improve its handling properties and control viscosity and storage stability.

Examples of the solvent (F) include:

ethylene glycol monoalkyl ether acetates such as ethylene glycol monomethyl ether acetate and ethylene glycol monoethyl ether acetate;

propylene glycol monoalkyl ethers such as propylene glycol monomethyl ether, propylene glycol monoethyl ether, propylene glycol monopropyl ether and propylene glycol monobutyl ether;

propylene glycol dialkyl ethers such as propylene glycol dimethyl ether, propylene glycol diethyl ether, propylene glycol dipropyl ether and propylene glycol dibutyl ether;

propylene glycol monoalkyl ether acetates such as propylene glycol monomethyl ether acetate, propylene glycol monoethyl ether acetate, propylene glycol monopropyl ether acetate and propylene glycol monobutyl ether acetate;

cellosolves such as ethyl cellosolve and butyl cellosolve;

carbitols such as butyl carbitol;

lactic acid esters such as methyl lactate, ethyl lactate, n-propyl lactate and isopropyl lactate;

aliphatic carboxylic acid esters such as ethyl acetate, n-propyl acetate, isopropyl acetate, n-butyl acetate, isobutyl acetate, n-amyl acetate, isoamyl acetate, isopropyl propionate, n-butyl propionate and isobutyl propionate;

other esters such as methyl 3-methoxypropionate, ethyl 3-methoxypropionate, methyl 3-ethoxypropionate, ethyl 3-ethoxypropionate, methyl pyruvate and ethyl pyruvate;

aromatic hydrocarbons such as toluene and xylene;

ketones such as 2-heptanone, 3-heptanone, 4-heptanone and cyclohexanone;

amides such as N-dimethylformamide, N-methylacetamide, N,N-dimethylacetamide and N-methylpyrrolidone; and

lactones such as γ-butyrolactone.

Of these, propylene glycol monomethyl ether acetate, ethyl lactate and propylene glycol monomethyl ether are preferable.

The solvents (F) may be used singly or two or more kinds may be used in combination.

In the photosensitive composition of the present invention, the content of the solvent (F) is usually 40 to 900 parts by mass, preferably 60 to 400 parts by mass based on 100 parts by mass of the total of components other than the solvent (F) in the composition.

### <Other Additives>

The photosensitive composition of the present invention may further comprise various additives such as leveling agents, surfactants, sensitizers and inorganic fillers in a range which is not detrimental to the object and properties of the present invention.

### <Preparation Method of Photosensitive Composition>

The photosensitive composition of the present invention can be prepared by homogenously mixing the individual components. A mixture obtained after homogenously mixing the individual components is usually subjected to filtration using a filter in order to remove contaminants.

### Cured Film

The cured film of the present invention is obtainable by curing the above photosensitive composition.

By using the photosensitive composition of the present invention, a cured film having small internal stress can be produced even after subjected to high-temperature steps. Thus, for example, in a silicon wafer neighboring the cured film of the present invention, warpage attributed to the internal stress of the cured film can be reduced.

Thus, the cured film of the present invention can be used suitably for surface-protecting films, flattening films, interlaminar insulating films, insulating film materials for high-density mounting substrates, photosensitive adhesives, pressure sensitive adhesives and the like of electronic parts such as circuit substrates (semiconductor devices), semiconductor packages and display devices.

An insulating film obtained from a photosensitive composition usually has internal stress. Consequently, the internal stress of the insulating film may cause a silicon wafer neighboring the insulating film to have warpage. In particular, in view of many plating flow steps in a mounting process in multilayer chip production and the increase in the diameter of the silicon wafer, the warpage tends to be larger. The cured film obtained from the photosensitive composition of the present invention has small internal stress, and therefore can suppress the warpage of the silicon wafer. Accordingly, such a film can be suitably used particularly as an interlaminar insulating film of an electronic part such as a multilayer chip that is produced through many high-temperature steps.

The cured film of the present invention can be produced, for example, by a process described hereinafter.

Specifically, the process for producing the cured film of the present invention comprises:

a step of applying the photosensitive composition of the present invention on a support to form a coating film (coating step);

a step of subjecting the above coating film via a desired mask pattern to exposure (exposure step); and

a step of developing the above coating film with an alkaline developing solution to dissolve and remove an exposed part (in the case of the positive photosensitive composition) or an unexposed part (in the case of the negative photosensitive composition) thereby forming the desired pattern on the support (development step), these steps being carried out in this order.

### [1] Coating Step

In coating step, the photosensitive composition of the present invention is applied on a support so that a finally-obtainable cured film (pattern) would have a thickness of e.g., 0.1 to 100 μm, and is dried with an oven or a hot plate, e.g., at a temperature of 50 to 140° C. for 10 to 360 seconds to thereby remove a solvent. Thereby, the coating film is formed on the support.

Examples of the support include a silicon wafer, a compound semiconductor wafer, a metal thin film-having wafer, a glass substrate, a quartz substrate, a ceramic substrate, an aluminum substrate and a substrate having a semiconductor chip on a surface of any of these supports. Examples of the coating method include dipping, spraying, bar coating, roll coating, spin coating, curtain coating, gravure printing, silk screen method and ink jet method.

### [2] Exposure Step

In exposure step, the coating film is subjected via a desired mask pattern to exposure, for example, using a contact aligner, a stepper or a scanner. Examples of the exposure light include ultraviolet light and visible light. Usually, a light with a wavelength of 200 to 500 nm (e.g., i-ray (365 nm)) is used. The activated light irradiation quantity varies depending on type and blending amount of the individual components in the photosensitive composition, the thickness of the coating film and the like, but the exposure quantity is usually 100 to 1500 mJ/cm² when i-ray is used as the exposure light.

The exposure may be followed by heat treatment (hereinafter also referred to as “PEB treatment”). PEB conditions, varying depending on contents of the individual components in the photosensitive composition, the film thickness and the like, are such that the treatment temperature is usually 70 to 150° C., preferably 80 to 120° C., and the treatment time is about 1 to 60 minutes.

### [3] Development Step

In development step, the above coating film is developed with an alkaline developing solution to dissolve and remove an exposed part (in the case of the positive photosensitive composition) or an unexposed part (in the case of the negative photosensitive composition), to thereby form the desired pattern on the support.

Examples of the development method include shower development, spray development, immersion development and puddle development. The development conditions are, for example, such that the development temperature is about 20 to 40° C. and the development time is about 1 to 10 minutes.

Examples of the alkaline developing solution include an alkaline aqueous solution obtained by dissolving, in water, an alkaline compound such as sodium hydroxide, potassium hydroxide, ammonia water, tetramethylammonium hydroxide and choline in order for the solution to have a concentration of 1 to 10% by mass. Into the above alkaline aqueous solution, for example, a water-soluble organic solvent such as methanol and ethanol, a surfactant and the like may be added in an appropriate amount. After development using an alkaline developing solution, the coating film may be washed with water and dried.

### [4] Thermal Treatment Step

After development step, in order to fully exhibit properties as an insulating film, the above pattern may be subjected to heat treatment for sufficient curing as needed. Curing conditions are not particularly limited. According to uses of the cured film, the film is heated, for example, at a temperature of 100 to 250° C. for about 30 minutes to 10 hours. In order for curing to sufficiently proceed or in order to prevent the deformation of the pattern shape, heating may be carried out through two stages. For example, at a first stage, the film is heated at a temperature of 50 to 100° C. for about 10 minutes to 2 hours, and at a second stage, the film is further heated at a temperature in the range of higher than 100° C. to not higher than 250° C. for about 20 minutes to 8 hours. Provided that the curing conditions are as described above, the heating equipment may be a typical oven, infrared furnace or the like.

### Electronic Part

The use of the photosensitive composition of the present invention can produce an electronic part comprising the above cured film: for example, an electronic part such as a circuit substrate (semiconductor device), a semiconductor package or a display device which has at least one cured film selected from a surface-protecting film, a flattening film and an interlaminar insulating film.

### EXAMPLES

Hereinafter, the present invention is described in greater detail with reference to Examples, but the present invention is in no way limited by these Examples. In Examples and Comparative Examples set forth hereinafter, “part(s)” is used to mean “part(s) by mass” unless otherwise noted.

### Measurement Method of Weight Average Molecular Weight (Mw)

Under conditions described below, Mw was measured by gel permeation chromatography.

Column: TSK-M and TSK2500, each of which is a column manufactured by Tosoh Corporation, were connected in series.

### Solvent: N,N-dimethylformamide

### Temperature: 40° C.

Detection method: refractive index method
Standard substance: polystyrene

### 1. Preparation of Photosensitive Composition

### Example 1

100 parts of an alkali soluble resin (A1-1), 25 parts of a photosensitive compound (B1-1), 20 parts of a crosslinking agent (C1-1), 10 parts of a crosslinking agent (C2-3) and 5 parts of an adhesion assistant (D-1) were dissolved in 180 parts of a solvent (F-1), to thereby prepare a photosensitive composition. The photosensitive composition obtained was used for its prescribed evaluations.

### Examples 2 to 7 and Comparative Examples 1 to 2

The same operation was performed as in Example 1, except that in Example 1, the type and the amount of the blending components were changed as shown in Table 1, to thereby prepare a photosensitive composition. The photosensitive compositions obtained were used for their prescribed evaluations.

Detail of the individual components in Table 1 is as follows:

(A1-1) o-cresol novolak resin (Mw=6200)
(A1-2) m-cresol novolak resin (Mw=7100)
(A1-3) m-cresol/p-cresol (6:4) novolak resin (Mw=5800)
(A′-1) polyimide precursor obtained in the following Synthesis Example 1

### Synthesis Example 1

Under the stream of dried nitrogen, 4.40 g (0.022 mol) of 4,4′-diaminobisphenyl ether (DAE) and 1.24 g (0.005 mol) of 1,3-bis(3-aminopropyl)tetramethyldisiloxane (SiDA) were dissolved in 50 g of N-methyl-2-pyrrolidone (NMP). Thereto, 21.4 g (0.030 mol) of a hydroxyl group-containing acid anhydride represented by the following formula 1 was added together with 14 g of NMP. The mixture was reacted at 20° C. for 1 hour, and then reacted at 40° C. for 2 hours. Thereafter, as a terminal-blocking agent, 0.71 g (0.006 mol) of 4-ethynylaniline was added, and the mixture was reacted at 40° C. for 1 hour. Then, a solution obtained by diluting 7.14 g (0.06 mol) of N,N-dimethylformamidedimethylacetal with 5 g of NMP was dropwise added for 10 minutes. After the dropwise addition, the mixture was stirred at 40° C. for 3 hours. After the completion of the reaction, the solution was poured into 2 L of water, and a precipitate of a polymer solid was collected by filtration. The polymer solid was dried in a vacuum drier set at 50° C. for 72 hours, thereby giving a polyimide precursor.

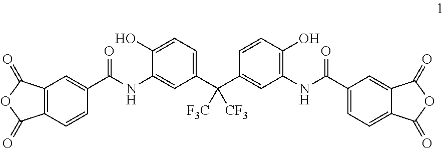

(B1-1) condensed product of 1,1-bis(4-hydroxyphenyl)-1-[4-{1-(4-hydroxyphenyl)-1-methylethyl]phenyl}ethane (1) and 1,2-naphthoquinone diazide-5-sulfonic acid (2) (molar ratio: {(1):(2)}=1.0:2.0)
(B1-2) condensed product of 1,1,1-tris(4-hydroxyphenyl)ethane (1) and 1,2-naphthoquinone diazide-5-sulfonic acid (2) (molar ratio: {(1):(2)}=1.0:2.0)
(C1-1) methoxymethylolated product of 1,1-bis(4-hydroxyphenyl)-1-[4-[1-(4-hydroxyphenyl)-1-methylethyl]phenyl]ethane (compound represented by the following formula 2)

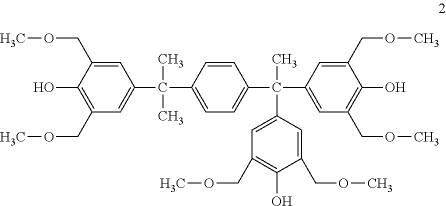

(C1-2) methoxymethylolated product of 1,1,1-tris(4-hydroxyphenyl)ethane (compound represented by the following formula 3)

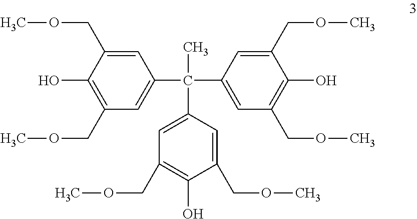

(C2-1) methylated melamine resin (manufactured by SANWA Chemical Co., Ltd., product name “MW-30M”) (C2-2) 1,1-bis[3,5-bis(methoxymethyl)-4-hydroxyphenyl]methane (compound represented by the following formula 4)

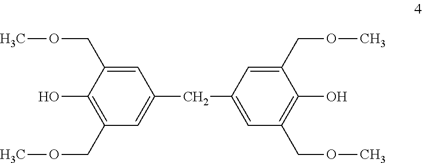

(C2-3) propylene glycol diglycidyl ether (manufactured by Kyoeisha
Chemical Co., Ltd., product name: EPOLIGHT 70P)
(C2-4) copolymer of phenylglycidyl ether and dicyclopentadiene (manufactured by Nippon Kayaku Co., Ltd., product name: XD-1000)
(D-1) γ-glycidoxypropyltrimethoxysilane
(E-1) crosslinked fine particles of a copolymer of butadiene, styrene, hydroxybutyl methacrylate, methacrylic acid and divinylbenzene
(butadiene/styrene/hydroxybutyl methacrylate/methacrylic acid/divinylbenzene=60/20/12/6/2 (% by mass); average primary particle diameter=65 nm)
(F-1) ethyl lactate

### 2. Evaluation

With regard to the photosensitive compositions of Examples and Comparative Examples, the following evaluations were made. The results are shown in Table 1.

### 2-1. Internal Stress of Insulating Film

The photosensitive composition was applied by spin coating on a silicon wafer of 8 inches, and then heated with a hot plate at 110° C. for 3 minutes, to prepare a resin coating film having a uniform thickness of 20 μm. Then, using Aligner (“MA-100” manufactured by Suss Microtec), the resin coating film was irradiated with ultraviolet light from a high-pressure mercury light in such a manner that the exposure quantity at a wavelength of 365 nm would be 500 mJ/cm². Then, the resin coating film was heated (PEB) with a hot plate at 110° C. for 3 minutes, and developed by being immersed in an aqueous tetramethylammonium hydroxide solution having a concentration of 2.38% by mass at 23° C. for 120 seconds. Then, the resin coating film was cured by heating with a convection type oven at 190° C. for 1 hour, to form an insulating film. With regard to the stress of the silicon wafer, the difference between before and after the formation of the insulating film was measured with a stress measurement apparatus (FLX-2320-s manufactured by TOHO Technology Corporation (technology formerly owned by KLA-Tencor)).

2-2. Resolution

The photosensitive composition was applied by spin coating on a silicon wafer of 6 inches, and then heated with a hot plate at 110° C. for 5 minutes, to prepare a resin coating film having a uniform thickness of 20 μm. Then, using Aligner (“MA-150” manufactured by Suss Microtec), the resin coating film was irradiated with ultraviolet light from a high-pressure mercury light via a mask pattern in such a manner that the exposure quantity at a wavelength of 350 nm would be 8000 J/m². Then, the resin coating film was developed by being immersed in an aqueous tetramethylammonium hydroxide solution having a concentration of 2.38% by mass at 23° C. for 180 seconds. Then, the developed resin coating film was washed with ultrapure water for 60 seconds, and dried by air. Thereafter, the film was observed with a microscope (MHL110 manufactured by OLYMPUS Corporation). The dimension of the resolved minimum pattern was defined as the resolution.

### 2-3. Thermal Shock Resistance

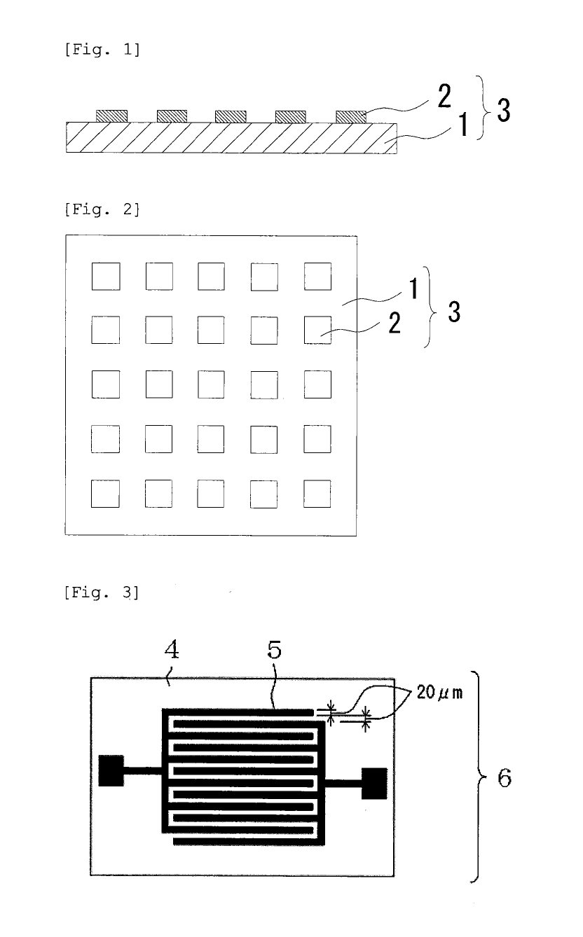

The photosensitive composition was applied on a base material 3 having a substrate 1 and a patterned copper foil 2 formed on the substrate 1 that was prepared for evaluation of thermal shock resistance as shown in FIG. 1 and FIG. 2. Then, the composition was heated with a hot plate at 110° C. for 5 minutes, to prepare a base material having a resin coating film with a thickness of 10 μm formed on the copper foil 2. Then, the resin coating film was cured by heating at 190° C. for 1 hour with a convection type oven, to prepare a cured film. The test base material obtained was subjected to resistance test with a thermal shock resistance tester (TSA-40L manufactured by ESPEC Corp.) wherein 1 cycle consisted of cooling at −65° C. for 30 minutes followed by heating at 150° C. for 30 minutes. After this treatment, the cured film was observed with a microscope at a magnification of 200 times. The number of cycles until the cured film underwent defects such as cracking was checked every 100 cycles.

### 2-4. Film Remaining Percentage

The photosensitive composition was applied by spin coating on a silicon wafer of 6 inches, and then heated with a hot plate at 110° C. for 3 minutes, to prepare a resin coating film having a uniform thickness of 20 μm. Then, using Aligner (“MA-150” manufactured by Suss Microtec), the resin coating film was irradiated with ultraviolet light from a high-pressure mercury light via a mask pattern in such a manner that the exposure quantity at a wavelength of 420 nm would be 500 mJ/cm². Then, the resin coating film was heated (PEB) with a hot plate at 110° C. for 3 minutes, and developed by being immersed in an aqueous tetramethylammonium hydroxide solution having a concentration of 2.38% by mass at 23° C. for 120 seconds. From the film thickness before development and a film thickness after development, the film remaining percentage was calculated.

### 2-5. Electrical Insulating Properties

The photosensitive composition was applied on a base material 6 having a substrate 4 and a patterned copper foil 5 formed on the substrate 4 that was prepared for evaluation of electrical insulating properties as shown in FIG. 3. Then, the composition was heated with a hot plate at 110° C. for 5 minutes, to prepare a base material having a resin coating film with a thickness of 10 μm formed on the copper foil 5. Then, the resin coating film was cured by heating at 200° C. for 1 hour with a convection type oven, to prepare a cured film. The test base material obtained was set in a migration evaluation system (AEI, EHS-221MD manufactured by ESPEC Corp.), and was treated at a temperature of 121° C., a humidity of 85%, a pressure of 1.2 atm, an applied voltage of 5 V for 200 hours. Then, the resistance value (Ω) of the test base material was measured to check electrical insulating properties.

TABLE 1

| | | | Ex. 1 | Ex. 2 | Ex. 3 | Ex. 4 | Ex. 5 | Ex. 6 | Ex. 7 | Co. Ex. 1 | Co. Ex. 2 |
|---|---|---|---|---|---|---|---|---|---|---|---|
| Blending | Alkali soluble | A1-1 | 100 | 100 | | | | | 90 | 70 | 100 |
| component | resin (A) | A1-2 | | | 100 | 100 | | | | | |
| of photosensitive | | A1-3 | | | | | 100 | 100 | | | |
| composition | | A′-1 | | | | | | | 10 | 30 | |
| (unit: part by | Photosensitive | B1-1 | 25 | 25 | 25 | 25 | | | 25 | 25 | 25 |
| mass) | compound (B) | B1-2 | | | | | 20 | 20 | | | |
| | Crosslinking | C1-1 | 20 | 20 | 20 | | 20 | | 20 | | |
| | agent (C) | C1-2 | | | | 20 | | 20 | | | |
| | | C2-1 | | | | | | | | 20 | |
| | | C2-2 | | | | | | | | | 20 |
| | | C2-3 | 10 | | | | 10 | | | 10 | 10 |
| | | C2-4 | | | 10 | 10 | | | | | |
| | Adhesion | D-1 | 5 | 5 | 5 | 5 | 5 | | | 5 | |
| | assistant (D) | | | | | | | | | | |
| | Crosslinked | E-1 | | 3 | 3 | | | | | | |
| | fine particles (E) | | | | | | | | | | |
| | Solvent (F) | F-1 | 180 | 180 | 180 | 180 | 180 | 180 | 180 | 180 | 180 |

| | | | | | | | | | | |
|---|---|---|---|---|---|---|---|---|---|---|
| Properties of | Internal stress (MPa) | 22 | 23 | 23 | 24 | 23 | 24 | 28 | 30 | 35 |
| photosensitive | Resolution (μm) | 5 | 5 | 5 | 5 | 5 | 5 | 5 | 10 | 20 |
| composition | Thermal shock | 2700 | 2600 | 2500 | 2700 | 2700 | 2500 | 2500 | 2000 | 1500 |
| | resistance (cycle) | | | | | | | | | |
| | Film remaining | 88 | 88 | 90 | 91 | 89 | 88 | 80 | 75 | 85 |
| | percentage (%) | | | | | | | | | |
| | Electrical insulating | >10¹¹ | >10¹¹ | >10¹¹ | >10¹¹ | >10¹¹ | >10¹¹ | >10¹¹ | >10¹¹ | >10¹¹ |
| | properties (Ω) | | | | | | | | | |

### REFERENCE SIGNS LIST

1 . . . substrate
2 . . . patterned copper foil
3 . . . base material for thermal shock resistance evaluation
4 . . . substrate
5 . . . patterned copper foil
6 . . . base material for electrical insulating properties evaluation

What is claimed is:

1. A photosensitive composition comprising an alkali soluble resin (A), a photosensitive compound (B) and a crosslinking agent (C), wherein the photosensitive composition comprises:
at least a novolak resin (A1) as the alkali soluble resin (A), the proportion of the content of the novolak resin (A1) being 80% by mass or more of the alkali soluble resin (A); and
at least a compound represented by the following formula (C1) as the crosslinking agent (C): 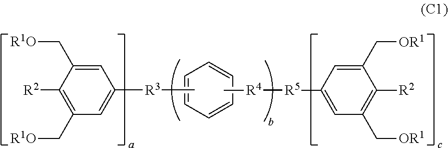
wherein R¹s are each independently a hydrogen atom, an alkyl group having 1 to 6 carbon atoms, —COR⁶ or —SO₂R⁷, wherein R⁶ is an alkyl group having 1 to 4 carbon atoms or a fluoroalkyl group having 1 to 4 carbon atoms, and R⁷ is a hydrocarbon group;
R²s are each independently hydroxyl group or a hydroxyalkyl group having 1 to 4 carbon atoms;
R³ is a (a+1)valent hydrocarbon group or a single bond; R⁵ is a (c+1)valent hydrocarbon group or a single bond, with the proviso that R³ and R⁵ are not single bonds at the same time;
R⁴ is a single bond, methylene group or an alkylene group;
“a” and “c” are each independently an integer of from 1 to 3, with the proviso that a+c is an integer of from 3 to 6; and
“b” is an integer of 0 or more.

2. The photosensitive composition according to claim 1, wherein the proportion of the content of the compound represented by the formula (C1) is 60% by mass or more of the crosslinking agent (C).

3. The photosensitive composition according to claim 1, wherein the photosensitive compound (B) is a quinone diazide compound (B1).

4. The photosensitive composition according to claim 2, wherein the photosensitive compound (B) is a quinone diazide compound (B1).

5. A cured film obtainable from the photosensitive composition according to claim 1.

6. A cured film obtainable from the photosensitive composition according to claim 2.

7. A cured film obtainable from the photosensitive composition according to claim 3.

8. A cured film obtainable from the photosensitive composition according to claim 4.

9. An electronic part comprising the cured film according to claim 5.

10. An electronic part comprising the cured film according to claim 6.

11. An electronic part comprising the cured film according to claim 7.

12. An electronic part comprising the cured film according to claim 8.
